(19) United States
(12) Patent Application Publication
(10) Pub. No.: US 2024/0424602 A1
(43) Pub. Date: Dec. 26, 2024

(54) FABRICATION OF PIXELATED RADIATION DETECTORS VIA LASER CUTTING

(71) Applicant: Northwestern University, Evanston, IL (US)

(72) Inventors: Mercouri G. Kanatzidis, Wilmette, IL (US); Yihui He, Evanston, IL (US)

(21) Appl. No.: 18/274,019

(22) PCT Filed: Jan. 28, 2022
(86) PCT No.: PCT/US22/14204

§ 371 Date: Jul. 25, 2023

Related U.S. Application Data
(60) Provisional application No. 63/142,625, filed on Jan. 28, 2021.

(51) Int. Cl. B23K 26/0622; B23K 26/38; B23K 101/40; B23K 103/00; B23K 103/08; G01T 1/24

(52) U.S. Cl. CPC B23K 26/0624; B23K 26/38; G01T 1/241; B23K 2101/40; B23K 2103/08; B23K 2103/52

(57) ABSTRACT

Methods of forming unipolar radiation detectors having pixelated anodes are provided. The radiation detectors include a pixelated anode layer are made by segmenting a continuous metal film on a semiconductor substrate using laser ablation with a picosecond or femtosecond laser pulse. The semiconductor from which the substrate is formed includes at least three elements, at least one of which is an element selected from period five or period six of the Periodic Table of the Elements and another of which is selected from S, Se, Te, Cl, F, I and Br. The methods allow for the efficient fabrication of pixels with a high pattern precision.

### CROSS-REFERENCE TO RELATED APPLICATIONS

The present application claims priority to U.S. provisional patent application No. 63/142,625 that was filed on Jan. 28, 2021, the entire contents of which are incorporated herein by reference.

### BACKGROUND

Large volume x-ray and γ-ray radiation detectors based on compound semiconductors with high stopping power have applications in homeland security, radiation level monitoring, astronomy, and medical imaging. In compound semiconductors, the imbalanced charge transport properties are persistently present, stemming from the asymmetric band structure for electron and hole carriers. Typically, the radiation detectors made from compound semiconductors are operated under a unipolar configuration. In the unipolar configuration, several device architectures, such as quasi-hemispherical, co-planar grid, pixelated, and capacitive Frisch grid type, have been developed and have demonstrated compelling performance improvements over the planar ambipolar configuration. The pixelated device architecture is dominant due to the feasibility for fabrication and fully-developed correction algorithms for ‘small pixel effect’, which ultimately leads to superb detector performance. Therefore, effectively fabricating a single-carrier device into a pixelated configuration is highly desirable for radiation detection applications.

Several approaches have been used for fabricating pixelated device architectures, including photolithography and photomask methods. Photolithography generally involves either an aqueous solution of a base (OH) or an organic solvent (such as 1-methyl-2-pyrrolidone) to remove the photoresist after patterning. This method works for II-VI chalcogenides, III-V semiconductors, and elemental semiconductors; however, it is not compatible with halide compounds, particularly for halide perovskite semiconductors. Halide perovskite semiconductors, such as CsPbBr₃, decompose in water or dissolve in organic solvents.

The photomask method is an easy and dry process to directly prepare patterned electrodes. However, certain drawbacks and limitations exist. The surrounding guard ring contacts for a radiation detector made using a photomask are typically divided to two sections due to the essential support needed for the central pixels mask regions. The divided guard rings can result in a distorted electric potential field compared to the non-divided ring contacts, and may have a negative influence on the charge transport efficiency at the nearby pixels.

### BRIEF DESCRIPTION OF THE DRAWINGS

Illustrative embodiments of the invention will hereafter be described with reference to the accompanying drawings, wherein like numerals denote like elements.

FIGS. 1A and 1B. 8×8 pixelated anode patterns with anode lateral dimensions of 1 mm (FIG. 1A) and 0.5 mm (FIG. 1B).

FIGS. 2A and 2B. A cross-sectional view (FIG. 2A) and a perspective view (FIG. 2B) of a radiation detector having a pixelated anode.

### SUMMARY

Methods of forming pixelated radiation detectors using laser ablation of a metal film on a semiconductor substrate to define a pixelated anode layer are provided. One example of a method of forming a pixelated radiation detector includes the steps of: forming a continuous metal film on a first surface of a photoactive semiconductor substrate, the photoactive semiconductor substrate comprising a semiconductor comprising at three elements, wherein at least one of the at least three elements is an element selected from period five or period six of the Periodic Table of the Elements and another of the three elements is selected from S, Se, Te, Cl, F, I and Br; forming an electrically conductive continuous electrode on a second, opposing surface of the photoactive semiconductor substrate; and cutting the continuous metal film on the first surface of the photoactive semiconductor substrate into a plurality of electrodes using picosecond or femtosecond timescale laser pulses, wherein the electrodes in the plurality of electrodes are separated and electrically isolated by gaps formed by the laser pulses.

### DETAILED DESCRIPTION

Methods of forming unipolar semiconductor-based radiation detectors having pixelated anodes are provided. The pixelated anodes are made by segmenting a continuous metal film deposited on a semiconductor substrate using pulsed laser cutting, which allows for the efficient fabrication of pixels with high pattern precision. The photoactive semiconductor substrate is composed of a semiconductor comprising at three elements, wherein at least one of the at least three elements is an element selected from period five or period six of the Periodic Table of the Elements and another of the three elements is selected from S, Se, Te, Cl, F, I and Br. In some examples of the radiation detectors, the semiconductor is a halide perovskite compound.

In the unipolar pixelated radiation detectors, a layer of photoactive halide perovskite is disposed between a pixelated anode layer, which is segmented into a plurality of anodes, and a common unsegmented cathode. Each pixel in the pixelated radiation detector is defined by the area between one of the anodes in the pixelated anode layer and the common cathode. The pixelated detector design is advantageous because it allows each pixel to be electronically addressed individually and makes it possible to identify the spatial location and timing of an interaction between the photoactive halide perovskite and an x-ray or a gamma-ray with a high resolution.

The laser cutting, which utilizes an ultrashort pulse laser source, can produce patterns of anodes in the pixelated anode layer, in which each anode is separated from its neighboring anodes by small gaps, such that the anodes are electrically isolated form one another. The anodes can be patterned into a variety of shapes, such as square, rectangular, and circular, and in a variety of arrangements. For example, anode arrays comprising a plurality of anodes can be formed in which the anodes are arranged in a regular pattern, such as a square grid or a honeycomb pattern, or an arbitrary pattern.

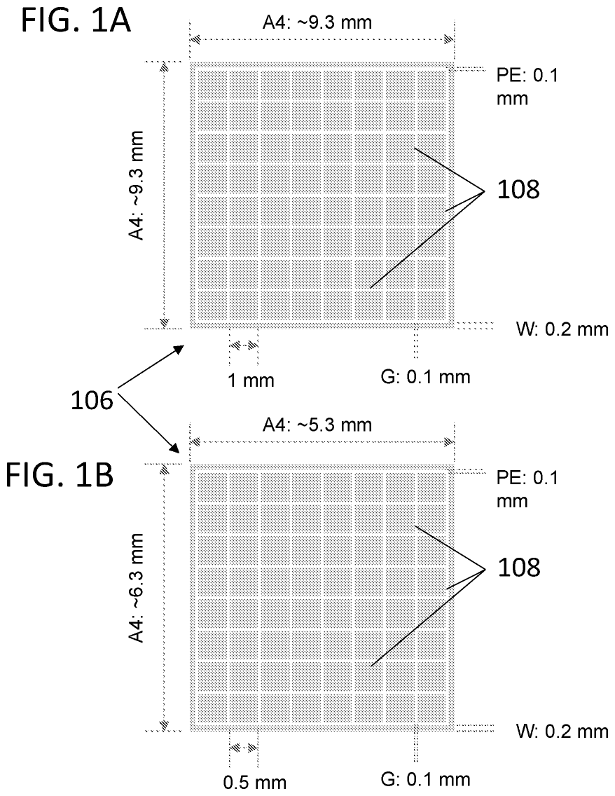

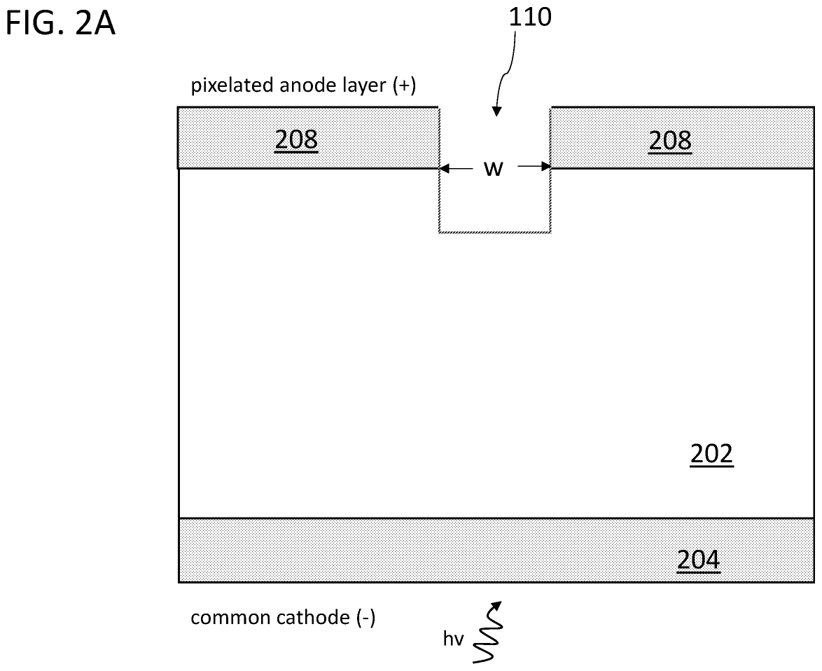

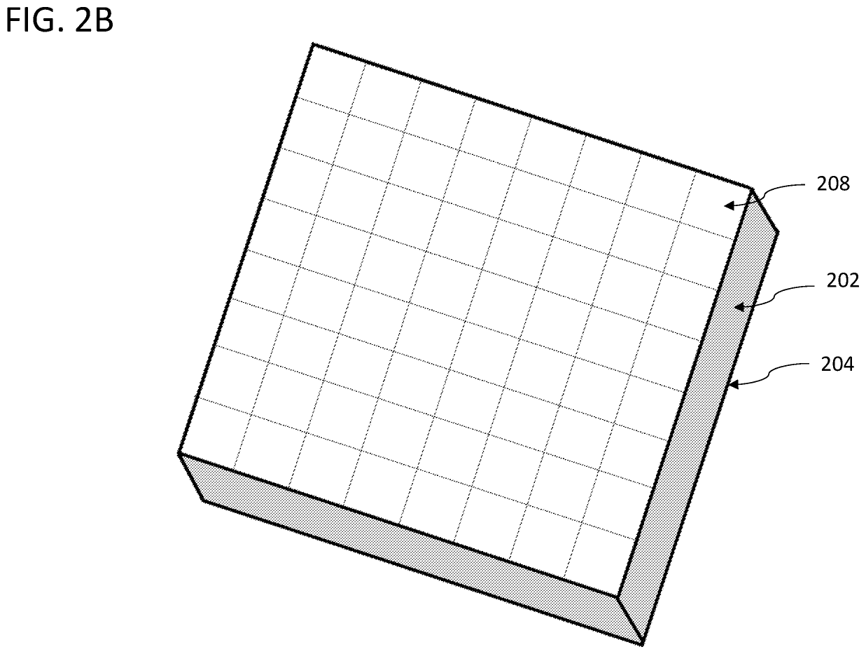

A detailed description of one embodiment of forming a pixelated anode layer on a metal halide perovskite substrate is provided in the Example. Top views of a radiation detector having a pixelated anode layer are shown schematically in FIGS. 1A and 1B. A cross-sectional side view of a radiation detector having a pixelated anode, which is referred to as a pixilated radiation detector, is shown in FIG. 2A and a perspective view of the pixelated radiation detector is shown in FIG. 2B. The pixelated radiation detector includes a single-crystal metal semiconductor substrate 202, with a continuous cathode 204 on one surface and a pixelated anode layer comprising a plurality of anodes 206 on the opposing surface. The individual anodes 208 that define the pixels are separated by gaps 210 of width ‘w’. As shown in FIG. 2A, the gaps may extend at least partially into halide perovskite substrate 202.

The pixelated anodes and the common cathode are composed of electrically conducting materials, typically metals such as gold or gold alloys. Other suitable metals include gallium, chromium, titanium, indium, platinum, indium, nickel, aluminum, bismuth, osmium and palladium, and alloys thereof. The metals can be deposited on the substrate surface as thin films by methods such as evaporation, vapor deposition, or sputtering. The metals films used for electrodes in hard radiation detection applications typically have a thickness of less than 500 nm; for example, metal films with thicknesses in the range from about 50 nm to 200 nm can be used. However, metal films with thicknesses outside of these ranges can also be used.

The laser cutting process uses ultrashort laser pulses to ablate a continuous metal film that is deposited on a surface of the semiconductor layer. The short laser pulses result in virtually no heat input, which reduces or eliminates damage to the semiconductor substrate below the anodes. Because the laser cutting can be computer-controlled, one can select the anode shapes and sizes. Another advantage of the laser cutting method is that it is a dry method and, therefore, no solvents or liquids are needed for the fabrication of the radiation detectors. Yet another advantage is that the laser cutting is quick, taking only tens of minutes (e.g., ≤30 minutes) to fabricate a pixelated anode.

The ultrashort laser pulses are picosecond or femtosecond timescale pulses delivered at a high pulse frequency. For the purposes of this disclosure, femtosecond timescale pulses include pulses from one to hundreds of femtoseconds (e.g., pulses in the range from 10⁻¹⁵ to 10⁻¹³ seconds), and picosecond timescale pulses include pulses from one to hundreds of picoseconds (e.g., pulses in the range from 10⁻¹² to 10⁻¹⁰ seconds). Laser pulses have a duration in the range from 5 fs to 1 ps are particularly useful for removing small amounts of metal with very little heat transfer. Suitable laser pulse frequencies include those in the range from 50 kHz to 500 kHz, including from 100 kHz to 200 kHz. The peak laser power should be maintained at a level that avoids damage to the halide perovskite substrate. The optimal peak laser power will depend on the pulse duration and frequency. However, generally peak laser powers in the range from 1 W to 10 W are suitable, including 3 W to 4 W.

The laser cutting can produce a pixelated anode layer having a high density of small anodes separated by gaps with small widths. For example, the anodes in an anode array can be separated by gaps with widths of less than 100 μm, less than 50 μm and less than 25 μm. By way of illustration, in some embodiments of the anode arrays, individual anodes in the pixelated anode layer are separated by gaps having widths (w) in the range from 20 μm to 100 μm. The anodes can have lateral dimensions (e.g., lengths and widths, or diameters) of, for example, 1000 μm or smaller, including 500 μm or smaller, 200 μm or smaller, and 50 μm or smaller. By way of illustration, anodes having lateral dimensions in the range from 10 μm to 1000 μm can be patterned into a metal layer. However, the anodes can be fabricated with gap widths and lateral dimensions outside of these ranges.

Arrays of the laser-patterned anodes can include many anodes over a large surface area. By way of illustration, arrays of at least 10, at least 100, at least 1000, or at least 10,000 anodes can be patterned over substrate surface areas of at least 1 cm², at least 10 cm², or at least 100 cm².

The pixelated anodes and the common cathode are configured to apply an electric field across the pixels defined in the semiconductor. The radiation detector further includes one or more voltage or current detectors configured to measure signal generated by electron-hole pairs that are formed when the semiconductor is exposed to incident radiation, such as an x-rays, gamma-rays, or alpha-particles. The pixelated anodes are electrically connected to the more or more voltage or current detectors, and can be individually addressed to enable the position of the source of the radiation within the semiconductor to be identified.

The pixelated radiation detectors can be used to detect hard radiation, such as gamma radiation or x-rays. A variety of ternary, or higher order, photoactive semiconductors comprising at least one element selected from period five or period six of the Periodic Table of the Elements and at least one element selected from S, Se, Te, Cl, F, I and Br can be used as substrate 202, wherein the term photoactive semiconductor refers to a semiconductor material that generates a photocurrent upon the absorption of radiation.

In embodiments of the radiation detectors in which the semiconductor substrate is a photoactive semiconductor, the halide perovskite may be an all-inorganic semiconductor or an organic-inorganic halide perovskite semiconductor. For example, the photoactive halide perovskite semiconductor can be a photoactive halide perovskite having the formula AMX₃, where A is a monovalent alkylammonium cation (for example, methylammonium, formamidinium, or a combination thereof) or an alkali metal cation (Group I cation), X is a halide ion, and M is an octahedrally coordinated bivalent metal atom. Examples of all-inorganic perovskites include compounds such as CsPbBr₃, CsPbCl₃, RbPbBr₃, and RbPbCl₃. Examples of hybrid organic-inorganic perovskites include compounds such as APbBr₃ and APbI₃, wherein A is methylammonium and/or formamidinium. Other suitable halide perovskites have the formula amAMX₃, where am is an alkyl diamine cation, an aromatic diamine cation, an aromatic azole cation, or a cyclic alkyl diamine cation. A is a monovalent alkylammonium cation or an alkali metal cation (Group I cation), X is a halide ion, and M is an octahedrally coordinated bivalent metal atom. The diamines can be primary, secondary, or tertiary diamines. Am can also represent a hydrazinediium cation. In some embodiments, am is an alkyl amine-functionalized aromatic azole, such as a histamine. In some embodiments, am is ethylenediamine, en. In these embodiments, the halide perovskites can be represented by the formula enAMX₃, wherein en is the ethylenediamine cation. In some embodiments, the am cation is an alkylene diammonium cation.

### Example

This example illustrates the use of laser cutting to fabricate a CsPbBr₃-based pixelated radiation detector. The laser cut was done by LPKF ProtoLaser R, with a picosecond laser module (1030 nm), and 1 ps pulse duration, max 200 kHz pulse frequency with a maximum power of 3.73 W.

As indicated in FIGS. 1A and 1B, the CsPbBr₃ pixelated detectors had anodes with lateral dimensions of 1 mm and 0.5 mm were fabricated. The electrode material was a 100 nm thick gold (Au) film on both radiation detectors. The Au electrode was prepared by thermal evaporation onto the surface of the CsPbBr₃. The laser cut removed the Au film between the pixels completely, accompanied by the removal of a few micrometers of the CsPbBr₃ substrate materials. This excludes the possibility of residual Au between the anodes, which might result in large leakage current between pixels.

The anode size and gap between the anodes can be controlled down to 50 μm, as shown in FIGS. 1A and 1B. Note that the laser beam size is around 15 μm and the minimum achievable cut width should be around 20 μm. Thus, the pixel size can be reduced by tuning the cutting parameters (such as laser power and feed rate). The laser cut was drawn-up using a digital 2D design program. Anodes with round shapes, rather than square shapes, were also patterned using the laser cutting system.

One of the great advantages of the laser cutting was its high efficiency for large scale fabrication, up to a substrate size of 12″×9″ or larger. For this example, the laser cutting was done on one 25 mm diameter CsPbBr₃ wafer, while the multiple anodes in the pixelated anode layer were created through one cut setting. An array of 64×32 anodes (2048 pixels) with 200 μm length and width dimensions and a 50 μm gap size was fabricated. All the anodes were cleanly cut, showing excellent completeness. Two arrays of 16×16 anodes (256 pixels) with 300 μm length and width dimensions and a 100 μm gap size were also fabricated. The laser power used was 0.25 W, the laser frequency was 200 kHz, and the laser feed rate was 600 mm/s.

This experiment demonstrates that laser cutting can be used to efficiently produce unipolar pixilated radiation detectors based on halide perovskites at high yields.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” can mean only one or can mean “one or more.” Embodiments of the inventions consistent with either construction are covered.

The foregoing description of illustrative embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

What is claimed is:

1. A method of forming a pixelated radiation detector, the method comprising:
forming a continuous metal film on a first surface of a photoactive semiconductor substrate, the photoactive semiconductor substrate comprising a semiconductor comprising at three elements, wherein at least one of the at least three elements is an element selected from period five or period six of the Periodic Table of the Elements and another of the three elements is selected from S, Se, Te, Cl, F, I and Br;
forming an electrically conductive continuous electrode on a second, opposing surface of the photoactive semiconductor substrate; and
cutting the continuous metal film on the first surface of the photoactive semiconductor substrate into a plurality of electrodes using picosecond or femtosecond timescale laser pulses, wherein the electrodes in the plurality of electrodes are separated and electrically isolated by gaps formed by the laser pulses.

2. The method of claim 1, wherein the semiconductor comprising at least three elements is a halide perovskite.

3. The method of claim 2, wherein the halide perovskite is an inorganic metal halide perovskite.

4. The method of claim 1, wherein the gaps extend into the semiconductor substrate.

5. The method of claim 1, wherein the gaps have widths of 100 μm or less.

6. The method of claim 1, wherein the gaps have widths of 50 μm or less.

7. The method of claim 1, wherein the anodes have at least one lateral dimension of 1000 μm or shorter.

8. The method of claim 3, wherein the metal halide perovskite is CsPbBr₃.

9. The method of claim 8, wherein the continuous metal film is a gold film.

10. The method of claim 9, wherein the gaps have widths of 50 μm or less and the anodes have lengths on widths of 1000 μm or shorter.

11. The method of claim 1, wherein the continuous metal film is a gold film.

12. The method of claim 1, wherein the radiation detector is a gamma-ray detector.

13. The method of claim 1, wherein the radiation detector is an x-ray detector.

14. The method of claim 1, wherein the radiation detector is an alpha-particle detector.
